(19) United States
(12) Patent Application Publication
(10) Pub. No.: US 2026/0089989 A1
(43) Pub. Date: Mar. 26, 2026

(54) HIGH VOLTAGE ALUMINUM NITRIDE DIODES WITH LOW IDEALITY FACTOR

(71) Applicants: Dinusha Herath Mudiyanselage, Mesa, AZ (US); Houqiang Fu, Chandler, AZ (US); Dawei Wang, Tempe, AZ (US)

(72) Inventors: Dinusha Herath Mudiyanselage, Mesa, AZ (US); Houqiang Fu, Chandler, AZ (US); Dawei Wang, Tempe, AZ (US)

(21) Appl. No.: 19/338,103

(22) Filed: Sep. 24, 2025

Related U.S. Application Data
(60) Provisional application No. 63/698,170, filed on Sep. 24, 2024.

(51) Int. Cl. H10D 8/60; H01L 23/31; H10D 62/85; H10D 62/854

(52) U.S. Cl. CPC H10D 8/60; H10D 62/8503; H10D 62/854; H10W 74/137

(57) ABSTRACT

A lateral Schottky barrier diode includes a single crystal AlN substrate, an unintentionally doped AlN layer, a silicon-doped AlN layer, an unintentionally doped GaN layer, a passivation layer, a plurality of ohmic contacts, and a Schottky contact.

### CROSS-REFERENCE TO RELATED APPLICATION

This application claims the benefit of U.S. Patent Application No. 63/698,170 filed on Sep. 24, 2024, which is incorporated by reference herein in its entirety.

### STATEMENT OF GOVERNMENT SUPPORT

This invention was made with government support under 2025490 and 2338604 awarded by the National Science Foundation and under DE-SC0021230 awarded by the Department of Energy. The government has certain rights in the invention.

### TECHNICAL FIELD

This invention relates to the fabrication of aluminum nitride Schottky barrier diode-based devices.

### BACKGROUND

Aluminum nitride is an ultra-wide bandgap semiconductor for high-voltage and high-temperature electronics. Silicon (Si) is used as an n-type dopant in AlN with a high ionization energy of ˜250 meV. At low doping levels, carbon impurities (CN) and dislocations act as the compensators, while at high doping levels, V_{Al}+nSi complexes reduce the free electron carrier concentration. Due at least in part to this behavior, free electron concentration is limited in Si-doped AlN epilayers. In addition, most metals have a Schottky-like behavior with AlN.

### SUMMARY

This disclosure describes lateral aluminum nitride (AlN) Schottky barrier diodes on single-crystal AlN substrates with an ultra-low ideality factor (n) of 1.65 and 640 V breakdown voltage (BV). The device current was dominated by thermionic emission.

In a first general aspect, a lateral Schottky barrier diode includes a single crystal AlN substrate, an unintentionally doped AlN layer, a silicon-doped AlN layer, an unintentionally doped GaN layer, a passivation layer, a plurality of ohmic contacts, and a Schottky contact.

Implementations of the first general aspect can include one or more of the following features.

In some cases, the unintentionally doped AlN layer is between the single crystal AlN substrate and the silicon-doped AlN layer. In some implementations, the silicon-doped AlN layer is between the unintentionally doped AlN layer and the unintentionally doped GaN layer. In certain cases, the unintentionally doped GaN layer is between the silicon-doped AlN layer and the passivation layer.

The plurality of ohmic contacts can extend through the passivation layer, the unintentionally doped GaN layer, and a portion of the silicon-doped AlN layer. In some cases, the Schottky contact extends through the passivation layer and is in contact with the unintentionally doped GaN layer. A concentration of the silicon in the silicon-doped AlN layer can be in a range of 1×10¹⁸ cm⁻³ to 1×10¹⁹ cm⁻³. In some implementations, the unintentionally doped AlN layer is homoepitaxially grown. A root mean square roughness of the unintentionally doped AlN layer can be in a range of 0.3 nm to 0.5 nm. In some examples, a dislocation density of the unintentionally doped AlN layer is in a range of 10³ cm⁻² to 10⁴ cm⁻⁵. A plurality of ohmic contacts can include a multi-layer metal stack. In some cases, the Schottky contact comprises a nickel layer and a gold layer. In some implementations, an ideality factor of the lateral Schottky barrier diode is between 1.6 and 1.7. An effective Schottky barrier height of the lateral Schottky barrier diode can be in a range of 1.9 eV to 2 eV. In some cases, a contact resistivity of the lateral Schottky barrier diode is in a range of 3×10⁻² Ωcm² to 4×10 Ωcm². In some implementations, a breakdown voltage of the lateral Schottky barrier diode is in a range between 630 V and 650 V at room temperature. A normalized breakdown voltage of the lateral Schottky barrier diode can be in a range of 125 V/μm and 130 V/μm at room temperature. In some cases, a thickness of the unintentionally doped AlN layer is in a range of 950 nm to 1050 nm. In some implementations, a thickness of the silicon-doped AlN layer is in a range of 150 nm to 250 nm. In some examples, a thickness of the unintentionally doped GaN layer is in a range of 1 nm to 5 nm. In some cases, a thickness of the passivation layer is in a range of 150 nm to 250 nm.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1A is a schematic diagram of a cross-section of the fabricated aluminum nitride (AlN) Schottky barrier diode. FIG. 1B shows forward current-voltage (I-V) characteristics on log and linear scales. FIG. 1C shows a (0002) rocking curve of AlN epilayers grown on single-crystal AlN substrate.

FIG. 2A shows I-V characteristics of transfer length method (TLM) structures at 298 K. FIG. 2B shows I-V characteristics of d=10 μm TLM structure from 298-573 K. FIG. 2C shows temperature-dependent sheet resistance (Rₛ) (square) and contact resistance (R_{c}) (circle) and FIG. 2D shows AlN film resistivity (ρ) (square) and contact resistivity (ρ_{c}) (circle) extracted from TLM measurements at 20 V.

FIG. 3A shows temperature-dependent I-V characteristics. FIG. 3B shows the effective Schottky barrier height (φ_{eff}) (solid circles) and ideality factor (η) of AlN Schottky barrier diodes (open circles).

FIG. 4 shows the breakdown characteristics of AlN Schottky barrier diode.

### DETAILED DESCRIPTION

This disclosure describes lateral aluminum nitride (AlN) Schottky barrier diodes on single-crystal AlN substrates with an ultra-low ideality factor (η) of 1.65 and 640 V breakdown voltage (BV). The Schottky barrier diodes were fabricated on single crystal AlN substrates by metalorganic chemical vapor deposition.

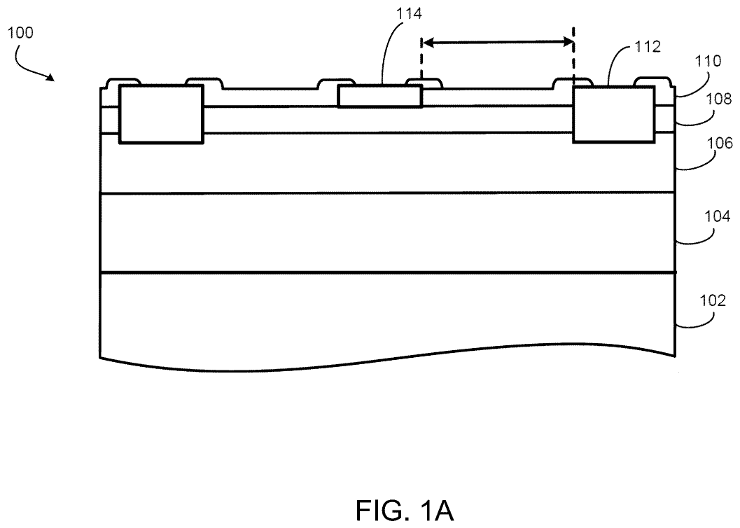

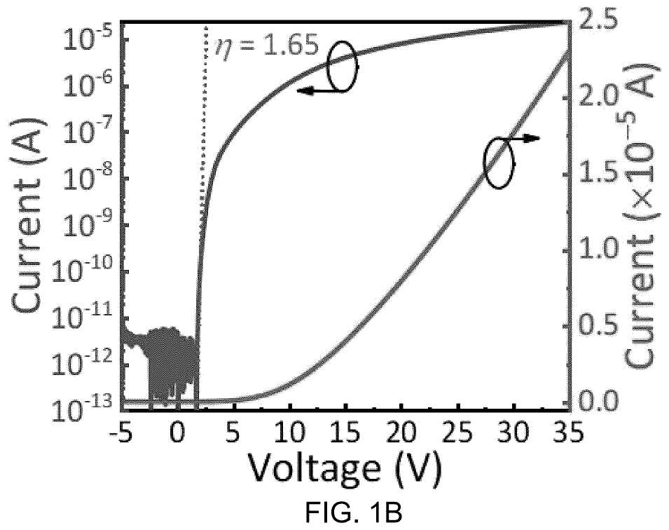

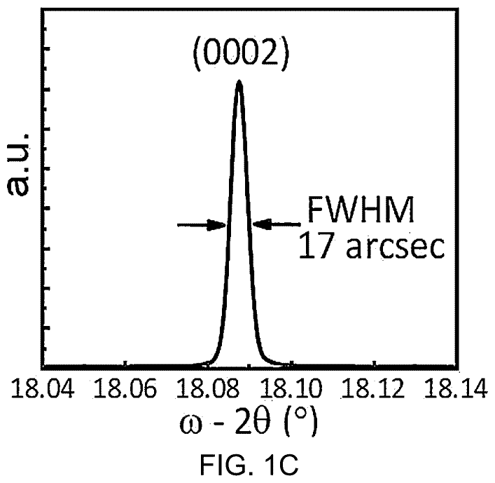

FIG. 1A is a schematic diagram of an example lateral Schottky barrier diode 100. The lateral Schottky barrier diode 100 includes a single crystal AlN substrate 102, an unintentionally doped AlN layer 104, a silicon-doped AlN layer 106, an unintentionally doped GaN layer 108, a passivation layer 110, a plurality of ohmic contacts 112, and a Schottky contact 114. Unintentional doping typically occurs when impurities are introduced accidentally or are present, for example, due at least in part to contamination during fabrication, residual impurities from the raw materials, diffusion from surrounding layers or substrates, or defects in the crystal lattice that behave like dopants. Examples of unintentional dopants include oxygen or carbon impurities.

Referring again to FIG. 1A, unintentionally doped AlN layer 104 is between the single crystal AlN substrate 102 and the silicon-doped AlN layer 106. A thickness of the unintentionally doped AlN layer 104 is typically in a range of 950 nm to 1050 nm (e.g., 1000 nm). A thickness of the silicon-doped AlN layer 106 is typically in a range of 150 nm to 250 nm (e.g., 200 nm). The silicon-doped AlN layer 106 is between the unintentionally doped AlN layer 104 and the unintentionally doped GaN layer 108. A thickness of the unintentionally doped GaN layer 108 is typically in a range of 1 nm to 5 nm (e.g., 2 nm). The unintentionally doped GaN layer 108 is between the silicon-doped AlN layer 106 and the passivation layer 110. A thickness of the passivation layer 110 is typically in a range of 150 nm to 250 nm (e.g., 200 nm). The plurality of ohmic contacts 112 extends through the passivation layer 110, the unintentionally doped GaN layer 108, and a portion of the silicon-doped AlN layer 106. The Schottky contact 114 extends through the passivation layer 110 and is in contact with the unintentionally doped GaN layer 108. A concentration of the silicon in the silicon-doped AlN layer 106 is in a range of 1×10¹⁸ cm³ to 1×10¹⁹ cm³.

The unintentionally doped AlN layer 104 is homoepitaxially grown. A root mean square roughness of the unintentionally doped AlN layer 104 is typically in a range of 0.3 nm to 0.5 nm. A dislocation density of the unintentionally doped AlN layer 104 is typically in a range of 10³ cm⁻² to 10⁴ cm⁻⁵. The plurality of ohmic contacts 112 can include a multi-layer metal stack. The Schottky contact 114 can include a nickel layer and a gold layer. An ideality factor of the lateral Schottky barrier diode 100 is between 1.6 and 1.7. An effective Schottky barrier height of the lateral Schottky barrier diode 100 is in a range of 1.9 eV to 2 eV. A contact resistivity of the lateral Schottky barrier diode 100 is in a range of 3×10⁻² Ωcm² to 4×10⁻² Ωcm². A breakdown voltage of the lateral Schottky barrier diode 100 is in a range of 630 V and 650 V at room temperature. A normalized breakdown voltage of the lateral Schottky barrier diode 100 is in a range of 125 V/m and 130 V/m at room temperature.

### Examples

Aluminum nitride (AlN) epilayers were grown on single-crystal AlN substrates (with a dislocation density approximately 10³ cm⁻²) by metalorganic chemical vapor deposition. Trimethylaluminum (TMAI) and ammonia (NH₃) were used as the precursors, while silane (SiH₄) was the n-type dopant. The growth temperature and pressure were 1250° C. and 20 Torr, respectively.

FIG. 1A is a schematic diagram of an example device structure. In an example, the device structure includes a 1-μm-thick AlN layer as a resistive buffer, a 200 nm highly Si-doped n-AlN layer, and a 2 nm unintentionally doped GaN capping layer. The Si doping concentration in the n-AlN layer was 1×10¹⁹ cm⁻³. The GaN capping layer was used to prevent oxidation of the underlying AlN epilayers upon exposure to air, which could degrade device performance.

The homoepitaxially grown AlN epilayer had a smooth surface morphology with root mean square (RMS) roughness of ˜0.4 nm by atomic force microscopy and low dislocation density on the order of 104 cm⁻² as measured by high-resolution X-ray diffraction, as shown in FIG. 1C. The full-width half maximum (FWHM) of the (0002) rocking curve was 17 arcseconds. The reduction of epilayer dislocation density by over three orders of magnitude compared to AlN layers on sapphire can be attributed at least in part to the use of single-crystal AlN substrates.

For the device fabrication, the sample first underwent a cleaning process involving acetone, isopropyl alcohol, and deionized water aided by ultrasonication, and hydrochloric acid to remove surface contaminations. The fabrication of AlN Schottky barrier diodes was performed using well-known optical photolithography and lift-off processes. Ohmic contacts were formed using Ti/Al/Ni/Au (25/100/25/50 nm) metal stacks deposited via electron beam (e-beam) deposition, followed by rapid thermal annealing at 950° C. in N₂ for 30 seconds. The circular ohmic contact had a width of 100 μm. Simultaneously with ohmic contacts, 100×200 μm rectangular transfer length method (TLM) structures were fabricated to measure the AlN ohmic contact behavior. Ni/Au (25/125 nm) metal stacks were deposited via e-beam evaporation as the Schottky contacts. The Schottky contact had a diameter of 100 μm, and the cathode-to-anode distance LAC was 5 μm. The devices were passivated using 200 nm SiO₂ by plasma-enhanced chemical vapor deposition. Finally, the contact vias were opened using fluorine-based (SF₆) reactive ion etching. Electrical measurements were performed on a probe station equipped with a Keithly 4200 SCS semiconductor analyzer and a thermal chuck. Reverse I-V characteristics were measured using Keysight B1505A power device analyzer/curve tracer, and reverse breakdown measurements were conducted in insulating Fluorinert liquid FC-70 at room temperature.

FIG. 1B shows the forward I-V characteristics of the AlN Schottky barrier diode on both log and linear scales. The ideality factor (η) and the Schottky barrier height (φ_{b}) have been calculated from equations (1) and (2),

$$J = {J}_{s} [ exp ( \frac{q ( V - IR )}{η k T} ) - 1 ] \qquad ( 1 )$$

$${J}_{s} = A * {T}^{2} exp ( - \frac{q {φ}_{b}}{k T} ) \qquad ( 2 )$$

where k, T, R, A*, Jₛ, and φ_{b} represent the Boltzmann constant, absolute temperature, series resistance, Richardson constant, reverse saturation current density, and Schottky barrier height, respectively. The Ob is typically replaced by effective Schottky barrier height φ_{eff} when η deviates from unity. The device showed an ultra-low η of 1.65 and a high φ_{eff} of 1.94 eV. The low n suggested that the current conduction was due at least in part to thermionic emission and defect-induced current is minimized. Additionally, the φ_{eff} of this device was also high (approximately 1.9 eV), comparable to those of AlN high-voltage devices predominantly governed by the defect-induced current transport.

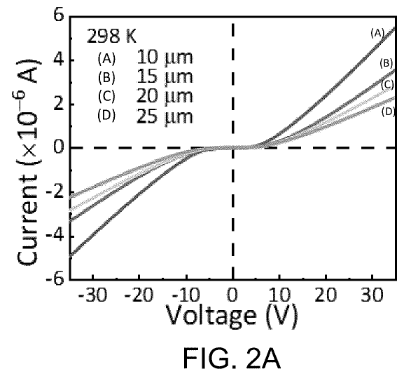

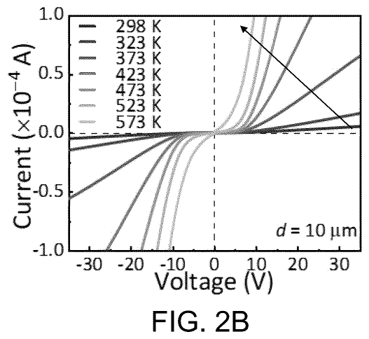

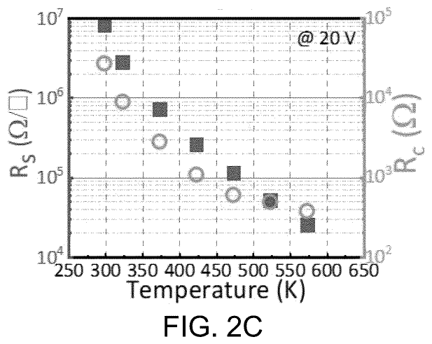

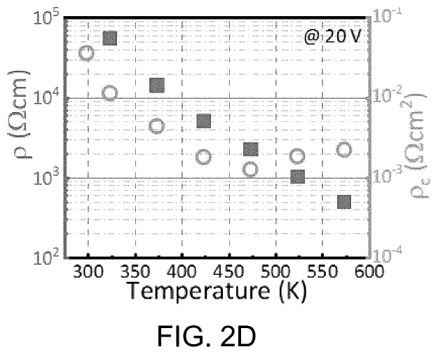

FIG. 2A shows AlN ohmic contact behavior at room temperature (e.g., 298 K). The current decreased as the gap between TLM pads (d) increased. The I-V behavior of the AlN ohmic contact was non-linear due at least in part to the ultrawide bandgap of AlN and low electron carrier concentration, which is observed in AlN and high Al-content AlGaN. The I-V measurements were conducted from 298 K to 573 K. FIG. 2B shows the I-V behavior for d=10 μm for all the temperatures up to 573 K. An arrow placed above the graph indicates the direction of increasing temperature. Referring to FIG. 2C, the film sheet resistance (Rₛ) and contact resistance (R_{c}) were calculated. The resistivity of AlN (p) and the contact resistivity (ρ_{c}) of ohmic contacts were subsequently extracted, as shown in FIG. 2D. Due at least in part to the nonlinear nature of the I-V measurements, the resistance is calculated at a certain voltage or current value. For example, the resistance is calculated at 20 V, by dividing the corresponding current (R=V/I). A reduced pe of 3.59×10⁻² Ωcm² at room temperature and a minimum value of 1.26×10 3 Ωcm² at 473 K were observed, which are comparable to high Al-content AlGaN. Furthermore, the obtained pc was also lower than that of Si-ion implanted AlN on sapphire at room temperature and high temperatures, where the latter showed the lowest comparable pe of 4.0×10⁻³ Ωcm² only at 1100 K.

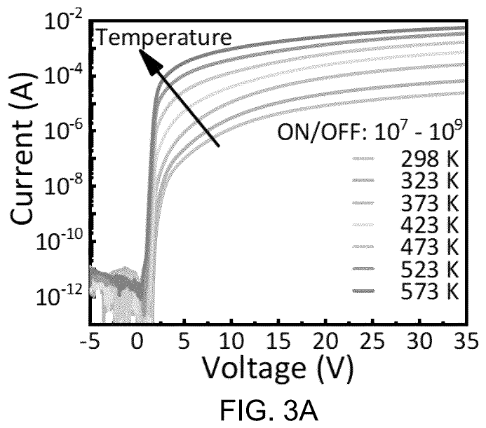

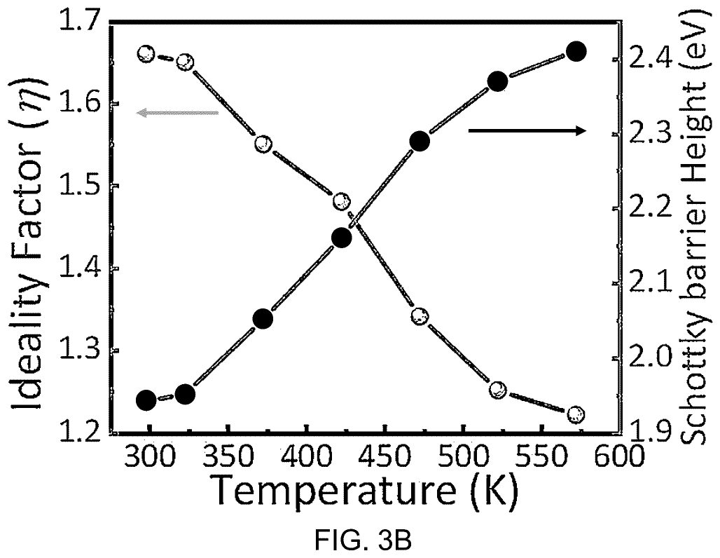

FIG. 3A shows the temperature-dependent I-V characteristics of the AlN Schottky barrier diodes. An arrow placed above the graph indicates the direction of increasing temperature. The device showed a high ON/OFF ratio of 107-109 as the temperature varied from 298 K to 573 K. Using the thermionic emission model, y and φ_{eff} were calculated at each temperature. The φ_{eff} increased from 1.94 to 2.41 eV, and the n decreased from 1.65 to 1.23 with increasing temperature. The φ_{eff} was in good agreement with the predicted value for Ni Schottky contacts. FIG. 3B shows the temperature-dependence of φ_{eff} and n of the devices. This behavior can be attributed at least in part to an inhomogeneous metal/semiconductor interface. In the presence of an inhomogeneous Schottky contact, the φ_{eff} tends to increase while the n decreases. At the metal/semiconductor interface, there are both low and high Schottky barrier regions. At low temperatures, electrons can only pass through regions with low Schottky barriers. However, at high temperatures, electrons gain sufficient momentum to cross regions with high Schottky barriers. Consequently, the φ_{eff} increases with temperature.

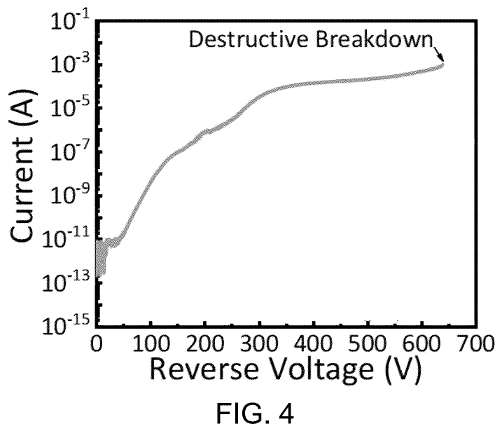

FIG. 4 shows the reverse breakdown measurements of the AlN Schottky barrier diodes under room temperature. The devices exhibited a breakdown voltage (BV) of 640 V, and the breakdown was destructive at the device edges due at least in part to the electric field crowding effect. Technology Computer-Aided Design (TCAD) simulations indicated a cause of breakdown could be the crowded electric field under the anode edge with a peak field of 4 MV/cm. Therefore, the Schottky barrier diodes showed high BV and ultra-low n simultaneously.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A lateral Schottky barrier diode comprising:
a single crystal AlN substrate;
an unintentionally doped AlN layer;
a silicon-doped AlN layer;
an unintentionally doped GaN layer;
a passivation layer;
a plurality of ohmic contacts; and
a Schottky contact.

2. The lateral Schottky barrier diode of claim 1, wherein the unintentionally doped AlN layer is between the single crystal AlN substrate and the silicon-doped AlN layer.

3. The lateral Schottky barrier diode of claim 1, wherein the silicon-doped AlN layer is between the unintentionally doped AlN layer and the unintentionally doped GaN layer.

4. The lateral Schottky barrier diode of claim 1, wherein the unintentionally doped GaN layer is between the silicon-doped AlN layer and the passivation layer.

5. The lateral Schottky barrier diode of claim 1, wherein the plurality of ohmic contacts extends through the passivation layer, the unintentionally doped GaN layer, and a portion of the silicon-doped AlN layer.

6. The lateral Schottky barrier diode of claim 1, wherein the Schottky contact extends through the passivation layer and is in contact with the unintentionally doped GaN layer.

7. The lateral Schottky barrier diode of claim 1, wherein a concentration of the silicon in the silicon-doped AlN layer is in a range of 1×10¹⁸ cm⁻³ to 1×10¹⁹ cm⁻³.

8. The lateral Schottky barrier diode of claim 1, wherein the unintentionally doped AlN layer is homoepitaxially grown.

9. The lateral Schottky barrier diode of claim 8, wherein a root mean square roughness of the unintentionally doped AlN layer is in a range of 0.3 nm to 0.5 nm.

10. The lateral Schottky barrier diode of claim 8, wherein a dislocation density of the unintentionally doped AlN layer is in a range of 10³ cm⁻² to 10⁴ cm⁻⁵.

11. The lateral Schottky barrier diode of claim 1, wherein the plurality of ohmic contacts comprises a multi-layer metal stack.

12. The lateral Schottky barrier diode of claim 1, wherein the Schottky contact comprises a nickel layer and a gold layer.

13. The lateral Schottky barrier diode of claim 1, wherein an ideality factor of the lateral Schottky barrier diode is between 1.6 and 1.7.

14. The lateral Schottky barrier diode of claim 1, wherein an effective Schottky barrier height of the lateral Schottky barrier diode is in a range of 1.9 eV to 2 eV.

15. The lateral Schottky barrier diode of claim 1, wherein a contact resistivity of the lateral Schottky barrier diode is in a range of 3×10⁻² Ωcm² to 4×10⁻² Ωcm².

16. The lateral Schottky barrier diode of claim 1, wherein a breakdown voltage of the lateral Schottky barrier diode is in a range between 630 V and 650 V at room temperature.

17. The lateral Schottky barrier diode of claim 1, wherein a normalized breakdown voltage of the lateral Schottky barrier diode is in a range of 125 V/μm and 130 V/μm at room temperature.

18. The lateral Schottky barrier diode of claim 1, wherein a thickness of the unintentionally doped AlN layer is in a range of 950 nm to 1050 nm.

19. The lateral Schottky barrier diode of claim 1, wherein a thickness of the silicon-doped AlN layer is in a range of 150 nm to 250 nm.

20. The lateral Schottky barrier diode of claim 1, wherein a thickness of the unintentionally doped GaN layer is in a range of 1 nm to 5 nm.

21. The lateral Schottky barrier diode of claim 1, wherein a thickness of the passivation layer is in a range of 150 nm to 250 nm.
